(19) United States
(12) Patent Application Publication
(10) Pub. No.: US 2024/0347533 A1
(43) Pub. Date: Oct. 17, 2024

(54) SELF-ALIGNED CONTACT WITH CT CUT AFTER RMG

(71) Applicant: INTERNATIONAL BUSINESS MACHINES CORPORATION, ARMONK, NY (US)

(72) Inventors: Ruilong Xie, Niskayuna, NY (US); Chanro Park, Clifton Park, NY (US); Min Gyu Sung, Latham, NY (US); Juntao Li, Cohoes, NY (US); Julien Frougier, Albany, NY (US)

(21) Appl. No.: 18/300,421

(22) Filed: Apr. 14, 2023

(51) Int. Cl. H01L 27/088; H01L 21/8234

(52) U.S. Cl. CPC H01L 27/088; H01L 21/823475; H01L 21/823481

(57) ABSTRACT

Embodiments of present invention provide a method of forming a semiconductor structure. The method includes forming a gate cut trench in a first region between a first and a second metal gate and in a second region between a first and a second source/drain region of a first and a second transistor respectively; depositing a dielectric liner in the trench lining sidewalls and a bottom of the trench; depositing a dielectric filler inside the trench above the dielectric liner, the dielectric liner thereby surrounding a bottom and sidewalls of the dielectric filler; depositing a dielectric cap covering the dielectric liner in the first region; etching the dielectric liner in the second region to create an opening exposing the source/drain region of the first transistor; and depositing a conductive material in the opening to form a source/drain contact of the first transistor. A structure formed thereby is also provided.

### BACKGROUND

The present application relates to manufacturing of semiconductor integrated circuits. More particularly, it relates to a method of forming self-aligned contact and the contact structure formed thereby.

With the continued scaling of semiconductor transistors and increased device density, it becomes more and more difficult to properly form source/drain contacts in a reduced pitch of space. In order to form the right size of contacts in the right place, a lithographic patterning process with high precision and/or high resolution may be needed.

On the other hand, processes for forming self-aligned contact (SAC) have been developed for the purpose of forming contacts in tight spaces such as in those nodes with contact poly pitch (CPP) less than 48 nm. The processes rely on etch selectivity of different materials in the contact area such that contacts larger than the contact area may be formed which will self-align with the contact area created in a selective etching process. However, in a gate cut (CT) post replacement-metal-gate (RMG) process, when source/drain contacts are to be formed that extend into the CT cut area after forming gate using the RMG process, the SAC process may not work due to the materials used in the current CT cut process. In other words, current process of CT cut is not compatible with the current SAC process.

### SUMMARY

Embodiments of present invention provide a semiconductor structure. The semiconductor structure includes a gate cut structure, the gate cut structure includes a first region, a second region, a dielectric liner, and a dielectric filler; the first region being between a first and a second gate of a first and a second transistor respectively; the second region being between a first and a second source/drain region of the first and the second transistor respectively; and the dielectric liner surrounding the dielectric filler at a bottom and sidewalls of the dielectric filler, where the dielectric filler has a first height and the dielectric liner in the first region between the first and the second gate of the first and the second transistor has a second height, and the second height is smaller than the first height.

In one embodiment, the dielectric liner in the second region between the first and the second source/drain region of the first and the second transistor has a third height and a fourth height, where the third height of the dielectric liner is substantially same as the first height of the dielectric filler.

In another embodiment, the fourth height is smaller than the third height and a portion of the dielectric liner having the fourth height is directly below a first source/drain contact of the first transistor.

According to one embodiment, the semiconductor structure further includes a dielectric cap above the first and the second gate of the first and the second transistor, where the dielectric cap has a top surface that is co-planar with the dielectric filler and has a fifth height that is substantially same as the first height of the dielectric filler and substantially same as the third height of the dielectric liner.

In one embodiment, the dielectric cap is directly on top of the dielectric liner between the first and the second gate of the first and the second transistor, the dielectric cap has an etch selectivity that is different from an etch selectivity of the dielectric filler and different from an etch selectivity of the dielectric liner.

In another embodiment, the first and the second transistor include low-k spacers at sidewalls of the first and the second gate respectively, and the dielectric liner includes a low-k dielectric material that is substantially same materially as the low-k spacers.

In yet another embodiment, the dielectric filler has an etch selectivity that is different from an etch selectivity of the dielectric liner and is substantially same materially as an interlevel dielectric layer on top of the first and the second source/drain region of the first and the second transistor.

Embodiments of present invention further provide a method of forming a semiconductor device. The method includes forming a gate cut trench in a first region between a first and a second metal gate of a first and a second transistor respectively and in a second region between a first and a second source/drain region of the first and the second transistor respectively; depositing a dielectric liner in the trench, the dielectric liner lining sidewalls and a bottom of the trench; depositing a dielectric filler inside the trench above the dielectric liner, the dielectric liner thereby surrounding a bottom and sidewalls of the dielectric filler; depositing a dielectric cap covering the dielectric liner in the first region; etching the dielectric liner in the second region to create an opening exposing the first source/drain region of the first transistor; and depositing a conductive metal layer in the opening to form a first source/drain contact of the first transistor.

In one embodiment, the first and the second transistor have low-k spacers at sidewalls of the first and the second metal gate respectively, and an interlevel dielectric (ILD) layer covering the first and the second source/drain region respectively.

In another embodiment, depositing the dielectric cap includes recessing the dielectric liner in the first region and the low-k spacers at sidewalls of the first metal gate of the first transistor; and depositing the dielectric cap above the recessed dielectric liner and above the recessed low-k spacers.

According to one embodiment, the method further includes recessing the first and the second metal gate to expose the dielectric liner in the first region and the low-k spacers at sidewalls of the first metal gate of the first transistor before recessing the dielectric liner and the low-k spacers.

According to another embodiment, the method further includes planarizing a top surface of the dielectric cap to expose the ILD layer covering the first source/drain region of the first transistor.

In one embodiment, etching the dielectric liner further includes etching the ILD layer in a selective etching process to create the opening, the opening being self-aligned with the first source/drain region of the first transistor.

In another embodiment, etching the dielectric liner further includes etching the dielectric filler to form the first source/drain contact of the first transistor, the first source/drain contact of the first transistor being partially on top of the dielectric liner.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, 1C, and 1D are demonstrative illustrations of cross-sectional views and a simplified illustration of top view of a semiconductor structure at a step of manufacturing thereof in accordance with one embodiment of present invention;

FIGS. 2A, 2B, 2C, and 2D are demonstrative illustrations of cross-sectional views and a simplified illustration of top view of a semiconductor structure at a step of manufacturing thereof in accordance with one embodiment of present invention;

FIGS. 3A, 3B, 3C, and 3D are demonstrative illustrations of cross-sectional views and a simplified illustration of top view of a semiconductor structure at a step of manufacturing thereof in accordance with one embodiment of present invention;

FIGS. 4A, 4B, 4C, and 4D are demonstrative illustrations of cross-sectional views and a simplified illustration of top view of a semiconductor structure at a step of manufacturing thereof in accordance with one embodiment of present invention;

FIGS. 5A, 5B, 5C, and 5D are demonstrative illustrations of cross-sectional views and a simplified illustration of top view of a semiconductor structure at a step of manufacturing thereof in accordance with one embodiment of present invention;

FIGS. 6A, 6B, 6C, and 6D are demonstrative illustrations of cross-sectional views and a simplified illustration of top view of a semiconductor structure at a step of manufacturing thereof in accordance with one embodiment of present invention;

FIGS. 7A, 7B, 7C, and 7D are demonstrative illustrations of cross-sectional views and a simplified illustration of top view of a semiconductor structure at a step of manufacturing thereof in accordance with one embodiment of present invention;

FIGS. 8A, 8B, 8C, and 8D are demonstrative illustrations of cross-sectional views and a simplified illustration of top view of a semiconductor structure at a step of manufacturing thereof in accordance with one embodiment of present invention;

FIGS. 9A, 9B, 9C, and 9D are demonstrative illustrations of cross-sectional views and a simplified illustration of top view of a semiconductor structure at a step of manufacturing thereof in accordance with one embodiment of present invention;

FIGS. 10A, 10B, 10C, and 10D are demonstrative illustrations of cross-sectional views and a simplified illustration of top view of a semiconductor structure at a step of manufacturing thereof in accordance with one embodiment of present invention;

FIGS. 11A, 11B, 11C, and 11D are demonstrative illustrations of cross-sectional views and a simplified illustration of top view of a semiconductor structure at a step of manufacturing thereof in accordance with one embodiment of present invention;

FIGS. 12A, 12B, 12C, and 12D are demonstrative illustrations of cross-sectional views and a simplified illustration of top view of a semiconductor structure at a step of manufacturing thereof in accordance with one embodiment of present invention; and

FIG. 13 is a demonstrative illustration of a flow-chart of a method of manufacturing a semiconductor structure in accordance with embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

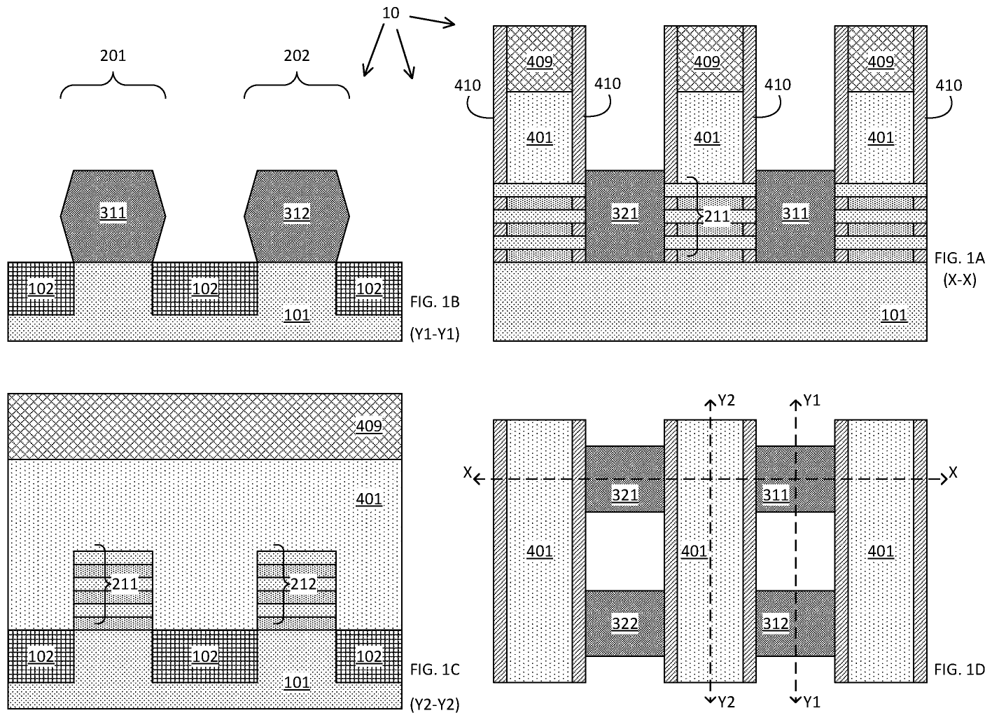

FIGS. 1A, 1B, and 1C are demonstrative illustrations of cross-sectional views, and FIG. 1D thereof according to one embodiment of present invention. More particularly, with reference to the simplified top view illustrated in FIG. 1D, FIG. 1A illustrates a cross-sectional view of the semiconductor structure, which may be a transistor structure 10 illustrated hereinafter as a non-limiting example, with the cross-section made along a dashed line X-X perpendicular to a gate and along one or more nanosheets from one source/drain region to another source/drain region of a transistor. FIG. 1B illustrates a cross-sectional view of the transistor structure 10 with the cross-section made along a dashed line Y1-Y1 across a source/drain region of the transistor, parallel to the gate and perpendicular to the one or more nanosheets. FIG. 1C illustrates a cross-sectional view of the transistor structure 10 with the cross-section made along a dashed line Y2-Y2 across the gate of the transistor, parallel to the gate and perpendicular to the one or more nanosheets. It is to be noted here that, being a simplified illustration of top view, FIG. 1D may not show each and every detailed feature of the transistor structure 10 at the particular step of manufacturing.

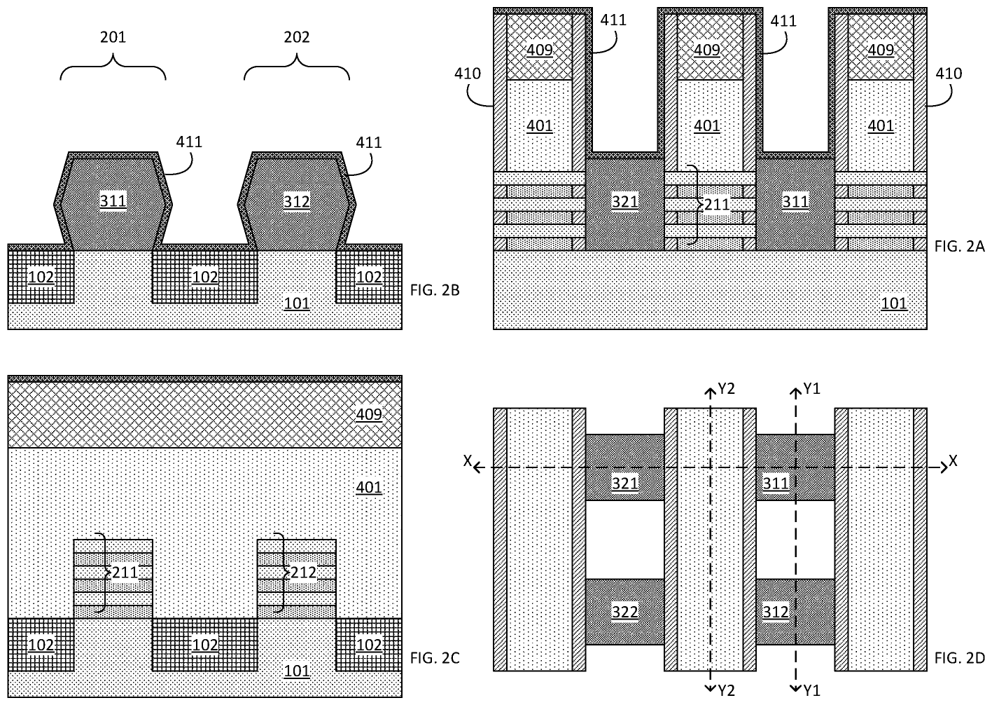

FIGS. 2A, 2B, 2C, and 2D to FIGS. 12A, 12B, 12C, and 12D are cross-sectional reviews and simplified top views of the transistor structure 10, at various manufacturing steps. They are demonstratively illustrated in a manner similar to FIGS. 1A, 1B, 1C, and 1D as described above.

Hereinafter, for the purpose of explanation of embodiments of present invention, the semiconductor structure is illustrated as a transistor structure and more particularly as a nanosheet transistor structure. However, embodiments of present invention are not limited to nanosheet transistor structures. For example, embodiments of present invention may be applied to fin-type transistor structures, planar transistor structures, or any other types of transistor structures and may even be applied to other non-transistor type of semiconductor structures.

Referring back to FIGS. 1A, 1B, 1C, and 1D, embodiments of present invention provide forming the transistor structure 10 by providing a semiconductor substrate 101. The substrate 101 may include, or may be formed now or at a later stage to include, one or more shallow-trench-isolations (STI's) 102 that are used to separate and/or electrically insulate one or more nanosheet transistors to be formed upon the substrate 101.

Embodiments of present invention may further provide forming one or more nanosheet transistors such as a first transistor 201 and a second transistor 202. The first transistor 201 may include a first stack of nanosheets 211 and the second transistor 202 may include a second stack of nanosheets 212. At a first end of the first and second stacks of nanosheets 211 and 212, the first transistor 201 may include a first source/drain region 311 and the second transistor 202 may include a second source/drain region 312. At a second end of the first and second stacks of nanosheets 211 and 212, the first transistor 201 may include a third source/drain region 321 and the second transistor 202 may include a fourth source/drain region 322. Dummy gates 401 may be formed on top of the first and the second stack of nanosheets 211 and 212 through a hard mask 409. Sidewall spacers 410 may be formed at sidewalls of the dummy gates 401. In one embodiment, the sidewall spacers 410 may be low-k spacers and may be made of low-k dielectric material such as, for example, silicon oxycarbide (SiOC).

FIGS. 2A, 2B, and 2C are demonstrative illustrations of cross-sectional views, and FIG. 2D is a simplified illustration of top view, of a semiconductor structure in a step of manufacturing thereof according to one embodiment of present invention. More particularly, following the step illustrated in FIGS. 1A-1D, embodiments of present invention provide forming a protective liner 411 to protect the low-k spacers 410. The protective liner 411 may be conformally formed through a deposition process on sidewalls of the low-k spacers 410. The protective liner 411 may also cover the source/drain regions 311, 312, 321, and 322 of the first and the second transistor 201 and 202 and cover the dummy gates 401 and the hard mask 409 on top thereof.

Here as is mentioned above, since FIG. 2D is a simplified illustration which is intended to show mainly the overall layout of source/drain regions and gates of the transistor structure 10, FIG. 2D may not necessarily show each and every feature of the transistor structure 10 at the particular step of manufacturing. For example, the protective liner 411 is intentionally omitted in FIG. 2D in order not to obscure the illustration of general layout of the transistor structure 10. Similar principles of illustration are applied to other top view illustrations hereinafter.

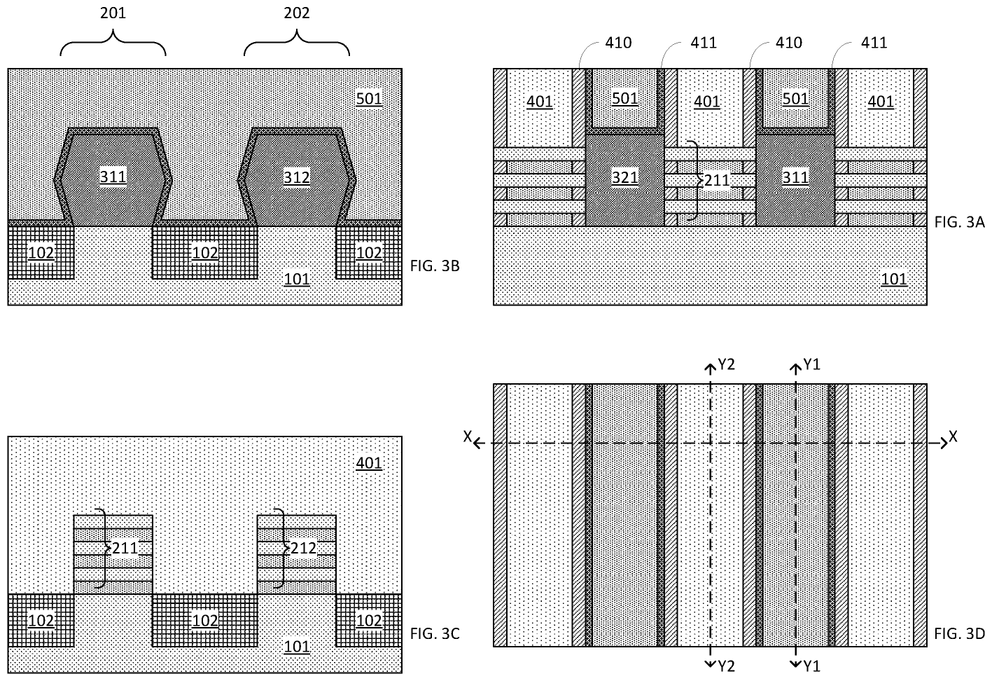

FIGS. 3A, 3B, and 3C are demonstrative illustrations of cross-sectional views, and FIG. 3D is a simplified illustration of top view, of a semiconductor structure in a step of manufacturing thereof according to one embodiment of present invention. More particularly, following the step illustrated in FIGS. 2A-2D, embodiments of present invention provide forming an interlevel dielectric (ILD) layer 501 on top of the source/drain regions 311, 312, 321, and 322 of the first and the second transistor 201 and 202. The ILD layer 501 may be formed by first depositing a blanket layer of dielectric material on top of the transistor structure 10, and subsequently applying a chemical-mechanic-polishing (CMP) process to planarize a top surface of the blanket layer of dielectric material to produce the ILD layer 501. For example, in one embodiment, the CMP process may be applied until the hard masks 409 on top of the dummy gates 401 are removed and the underneath dummy gates 401 are exposed as illustrated in FIG. 3A. The CMP process may also expose top surfaces of the low-k spacers 410 and the protective liners 411 next to the low-k spacers 410.

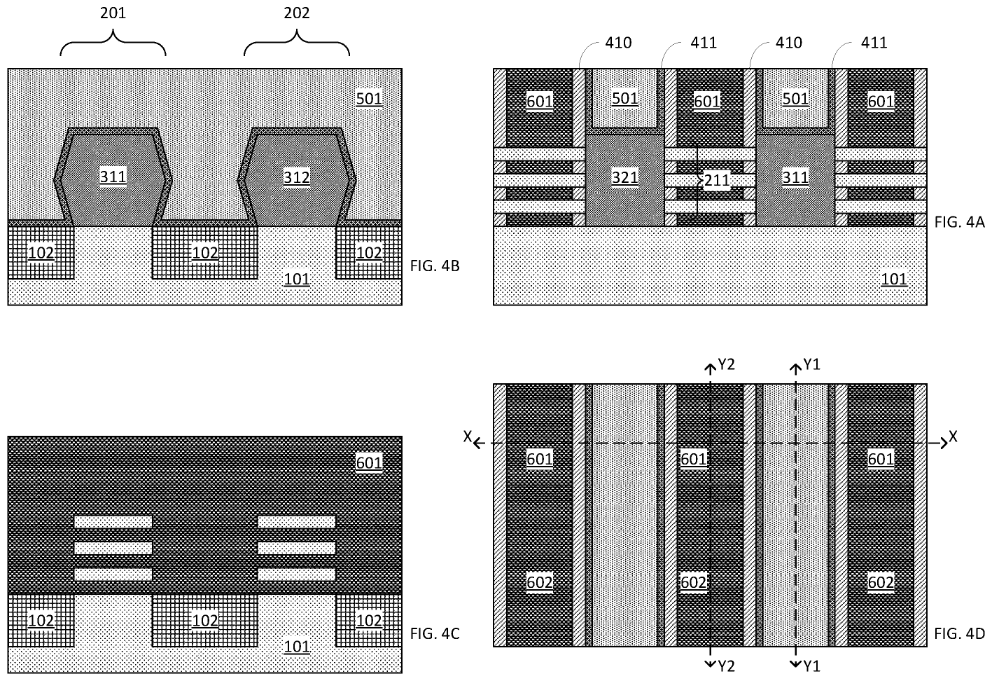

FIGS. 4A, 4B, and 4C are demonstrative illustrations of cross-sectional views, and FIG. 4D is a simplified illustration of top view, of a semiconductor structure in a step of manufacturing thereof according to one embodiment of present invention. More particularly, following the step illustrated in FIGS. 3A-3D, embodiments of present invention provide selectively removing the dummy gates 401 that are on top of the first and the second stack of nanosheets 211 and 212, and selectively removing a plurality of suspension sheets that are between, and separate, the individual nanosheets of the first and the second stack of nanosheets 211 and 212. The suspension sheets may be silicon-germanium (SiGe) sheets having a certain germanium (Ge) content level. The removal may be made through a SiGe release process that selectively removes the plurality of suspension sheets, based on the level of Ge content, relative to the individual nanosheets that are generally silicon nanosheets.

After removing the plurality of suspension sheets thereby creating openings that surround the individual nanosheets of the first and the second stack of nanosheets 211 and 212, embodiments of present invention provide filling the openings with gate materials to form a first metal gate 601 above and surrounding the first stack of nanosheets 211 and a second metal gate 602 above and surrounding the second stack of nanosheets 212. The gate materials may include, for example, a layer of gate dielectric material such as SiO₂, HfO₂, HfLaOx, HfAlOx etc., a layer of work function metal (WFM) such as TiN, TiAl, TiAlC, etc., and a conductive metal layer such as W, Al, etc. After the deposition of the conductive metal layer, a CMP process may be applied to planarize the top surface of the conductive metal layer.

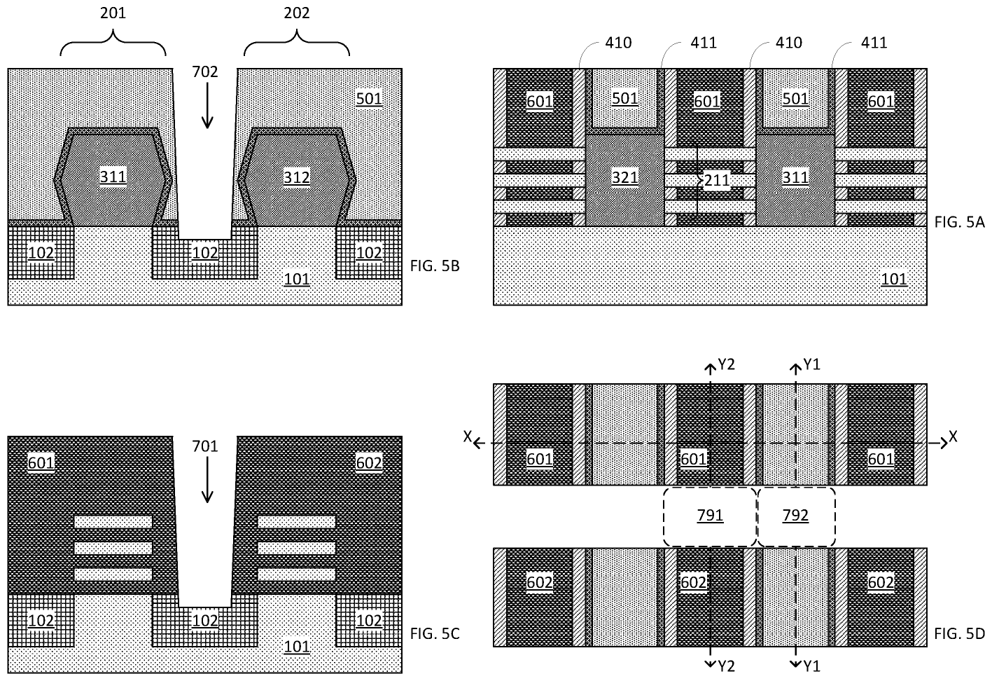

FIGS. 5A, 5B, and 5C are demonstrative illustrations of cross-sectional views, and FIG. 5D is a simplified illustration of top view, of a semiconductor structure in a step of manufacturing thereof according to one embodiment of present invention. More particularly, following the step illustrated in FIGS. 4A-4D, embodiments of present invention provide forming a gate cut trench 701 in a first region 791 between the first and the second metal gate 601 and 602 of the first and the second transistor 201 and 202, and forming a gate cut trench 702 in a second region 792 between the first and the second source/drain region 311 and 312 of the first and the second transistor 201 and 202. The gate cut trench 701 and 702, known as CT cut trench, may cut through the ILD layer 501, and the first and the second metal gate 601 and 602, and into one of the STI 102 in the substrate 101 to have a bottom and sidewalls thereof.

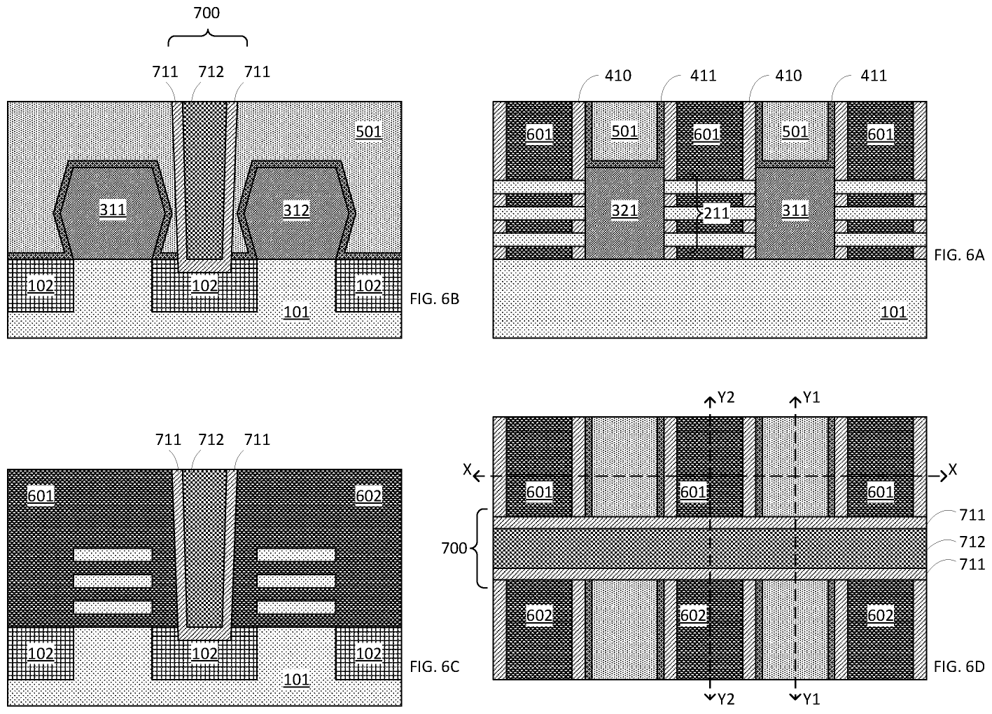

FIGS. 6A, 6B, and 6C are demonstrative illustrations of cross-sectional views, and FIG. 6D is a simplified illustration of top view, of a semiconductor structure in a step of manufacturing thereof according to one embodiment of present invention. More particularly, following the step illustrated in FIGS. 5A-5D, embodiments of present invention provide depositing a dielectric liner 711 in the gate cut trench 701 in the first region 791 and in the gate cut trench 702 in the second region 792 lining sidewalls and bottom of the gate cut trench 701 and 702. The dielectric liner 711 may be a low-k liner made of a material such as SiOC. In one embodiment, the dielectric liner 711 may be made of a material that is substantially same as that of the low-k spacers 410 at the sidewalls of the first and the second metal gate 601 and 602 of the first and the second transistor 201 and 202.

Embodiments of present invention may further provide depositing a dielectric filler 712 inside the gate cut trench 701 and 702 and above the dielectric liner 711. Consequently, the dielectric liner 711 may surround a bottom and sidewalls of the dielectric filler 712. The dielectric filler 712 may be made from a material such as, for example, silicon-dioxide (SiO₂) that has a different etch selectivity from an etch selectivity of the dielectric liner 711. In one embodiment, the difference in etch selectivity may be made sufficiently big such that it enables a selective etching process. The dielectric liner 711 protects the work-function metal (WFM) of the first and the second metal gate 601 and 602 from possible contamination by the dielectric filler 712. The deposition of the dielectric liner 711 and the dielectric filler 712 in the gate cut trench 701 and 702 form a gate cut structure 700 between the first and the second gate 601 and 602 and between the first and the second source/drain region 311 and 312 of the first and the second transistor 201 and 202.

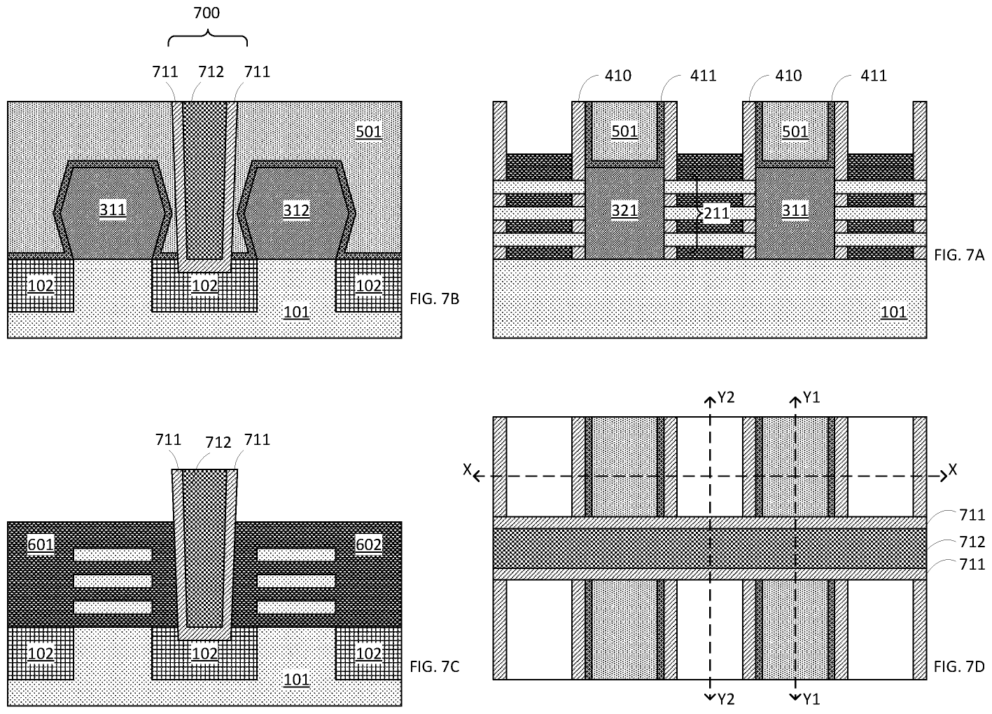

FIGS. 7A, 7B, and 7C are demonstrative illustrations of cross-sectional views, and FIG. 7D is a simplified illustration of top view, of a semiconductor structure in a step of manufacturing thereof according to one embodiment of present invention. More particularly, following the step illustrated in FIGS. 6A-6D, embodiments of present invention provide recessing the first and the second metal gate 601 and 602 such that sidewalls of at least an upper portion of the dielectric liner 711 at the first region 791 may be exposed. The recessing of the first and the second metal gate 601 and 602 may also expose sidewalls of an upper portion of the low-k spacers 410 of the first and the second metal gate 601 and 602. The recessing may stop well before exposing any nanosheets of the first and the second stack of nanosheets 211 and 212.

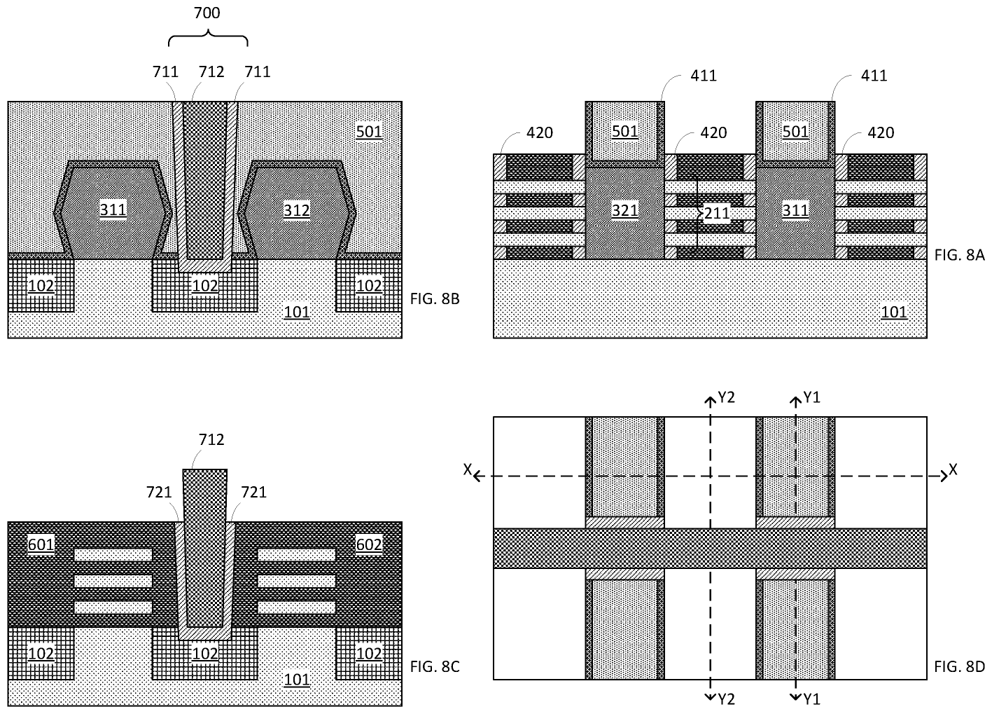

FIGS. 8A, 8B, and 8C are demonstrative illustrations of cross-sectional views, and FIG. 8D is a simplified illustration of top view, of a semiconductor structure in a step of manufacturing thereof according to one embodiment of present invention. More particularly, following the step illustrated in FIGS. 7A-7D, embodiments of present invention provide selectively removing portions of the low-k spacers 410 and the portions of the dielectric liner 711 that are exposed by the recessing of the first and the second metal gate 601 and 602. Removing the portions of the low-k spacers 410 may expose the protective liner 411 that surrounds the ILD layer 501 above the source/drain regions of the transistors as is illustrated in FIG. 8A. On the other hand, removing the portions of the dielectric liner 711 exposes an upper portion of the dielectric filler 712 previously surrounded by the dielectric liner 711, and in the meantime results in a dielectric liner 721, recessed from the dielectric liner 711, that has a top surface that is substantially co-planar with a top surface of the first and the second metal gate 601 and 602 as is illustrated in FIG. 8C.

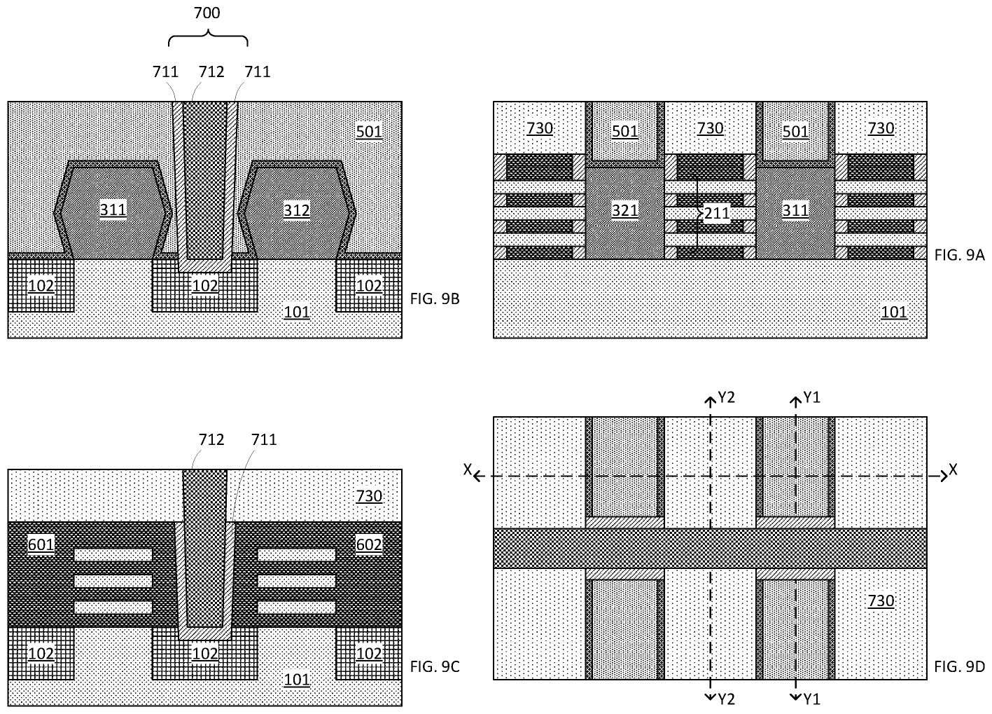

FIGS. 9A, 9B, and 9C are demonstrative illustrations of cross-sectional views, and FIG. 9D is a simplified illustration of top view, of a semiconductor structure in a step of manufacturing thereof according to one embodiment of present invention. More particularly, following the step illustrated in FIGS. 8A-8D, embodiments of present invention provide depositing a dielectric material on top of the recessed first and second metal gate 601 and 602, recessed low-k spacers 410, and the dielectric liner 721 (of the recessed dielectric liner 711) to form a dielectric cap 730. For example, after the deposition of the dielectric material, a CMP process may be applied to planarize a top surface of the dielectric cap 730 such that the dielectric cap 730 and the dielectric filler 712 may have a co-planar top surface, as is illustrated in FIG. 9C.

According to one embodiment of present invention, since no dielectric liner 711 is recessed in the second region between the first and the second source/drain region 311 and 312 of the first and the second transistor 201 and 202, no dielectric cap 730 is formed on top of the dielectric liner 711 in the second region. The dielectric liner 711 in the second region may be selectively etched away, in a subsequent process of forming a self-aligned source/drain contact as being described below in more details, while the dielectric cap 730 may protect the low-k spacers and the dielectric liner 721, i.e., the recessed dielectric liner 711, in the first region between the first and the second metal gate 601 and 602. In other words, embodiments of present invention enables a process of forming self-aligned contact (SAC) with gate cut formation after forming metal gate in a replacement-metal-gate (RMG) process. The process of forming SAC is particularly important in forming nodes where CPP is less than 48 nm because using non-SAC process in forming source/drain contact may not be an available option.

The dielectric cap 730 may be made of a material which includes, for example, SiN, SiBCN, and/or SiOCN that has a high etch selectivity relative to the etch selectivity of the dielectric liner 711 and 721, which may be substantially similar to the low-k spacers 410. The dielectric cap 730 also has a high etch selectivity relative to the dielectric filler 712. Strategically applying the difference in etch selectivity, embodiments of present invention enables a process of forming SAC to be compatible with the RMG process.

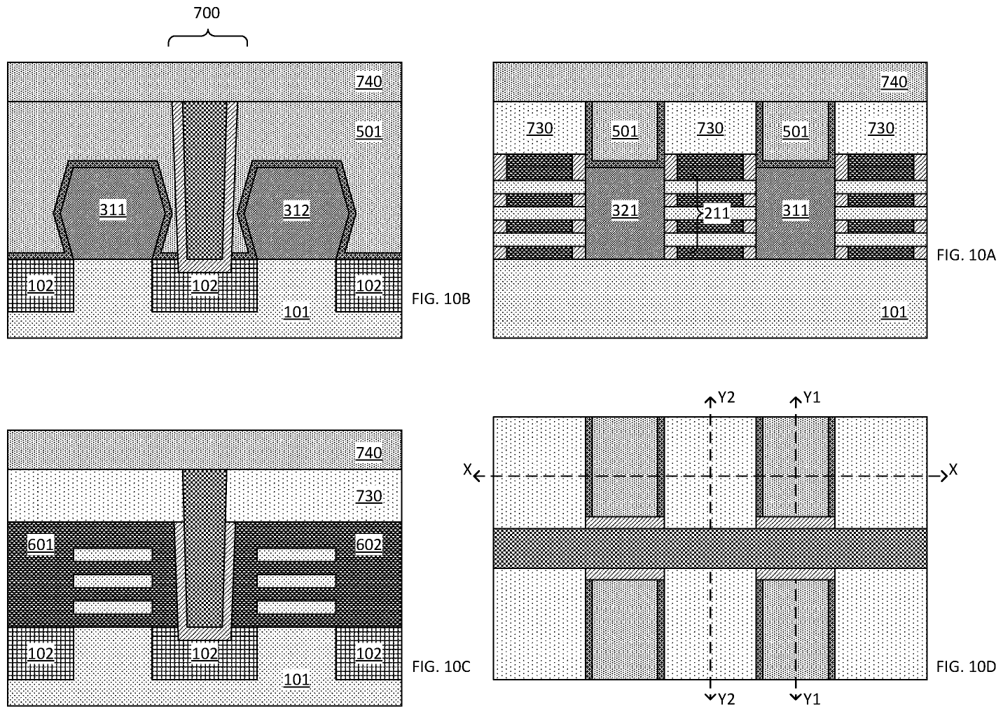

FIGS. 10A, 10B, and 10C are demonstrative illustrations of cross-sectional views, and FIG. 10D is a simplified illustration of top view, of a semiconductor structure in a step of manufacturing thereof according to one embodiment of present invention. More particularly, following the step illustrated in FIGS. 9A-9D, embodiments of present invention provide forming one or more additional ILD layers such as an ILD layer 740 as part of a middle-of-line (MOL) structure. The ILD layer 740 may be a same material as the ILD layer 501 however embodiments of present invention are not limited in this aspect. The ILD layer 740 may cover the dielectric cap 730, the dielectric filler 712, and the ILD layers 501 on top of the first and the second source/drain regions 311 and 312 of the first and the second transistor 201 and 202.

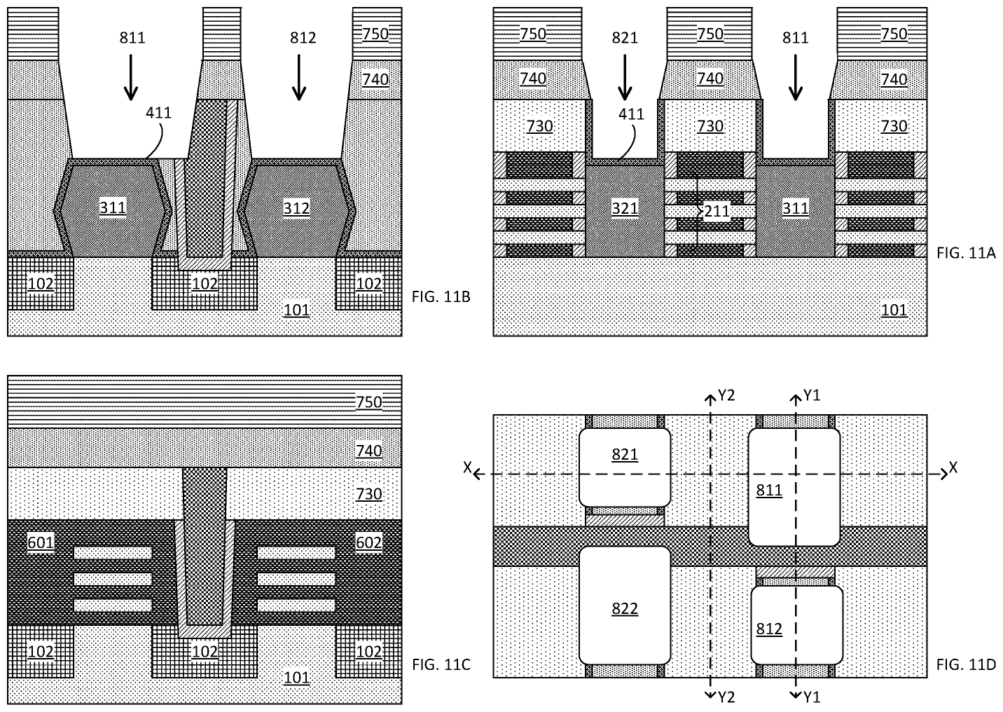

FIGS. 11A, 11B, and 11C are demonstrative illustrations of cross-sectional views, and FIG. 11D is a simplified illustration of top view, of a semiconductor structure in a step of manufacturing thereof according to one embodiment of present invention. More particularly, following the step illustrated in FIGS. 10A-10D, embodiments of present invention provide forming a hard mask 750 and using the hard mask 750 in a lithographic patterning and etching process to create openings in the ILD layer 740 and the ILD layer 501 to expose the source/drain regions of the transistors. For example, in one embodiment, an opening 811 may be created using a selective etching process to expose the underneath first source/drain region 311 of the first transistor 201. The etching process may etch the ILD layer 740, the ILD layer 501, the dielectric liner 711, and the dielectric filler 712, as is illustrated in FIG. 11B. The dielectric liner 711 and the dielectric filler 712 may be low-k dielectrics such as SiO₂ or SiOC with their k value around 4. On the other hand, the etching process may not etch the dielectric cap 730, and neither the protective liner 411, which may be high-k dielectrics such as SiN with their k value being around 7. In other words, the dielectric cap 730 and the protective liner 411 may have a different etch selectivity such that they are not affected during the selective etching process in the creation of the opening 811. The resulting opening 811, as is illustrated in FIG. 11A, is self-aligned to the first source/drain region 311 of the first transistor 201. More particularly, the opening 811 is self-aligned lengthwise along the length of the first source/drain region 311.

In one embodiment, the opening 811 may not only expose the first source/drain region 311 of the first transistor 201, it may also extend, widthwise and as is demonstratively illustrated in FIG. 11B, across the left side portion of the dielectric liner 711 and partially into the dielectric filler 712. It is to be noted here that the opening 811, in the widthwise direction, may not be self-aligned. In one embodiment, additional openings such as openings 812, 821, and 822 may be created in a same or different selective etching process to expose the source/drain regions 312, 321, and 322 respectively. The openings 811, 812, 821, and 822 may be created for forming source/drain contacts.

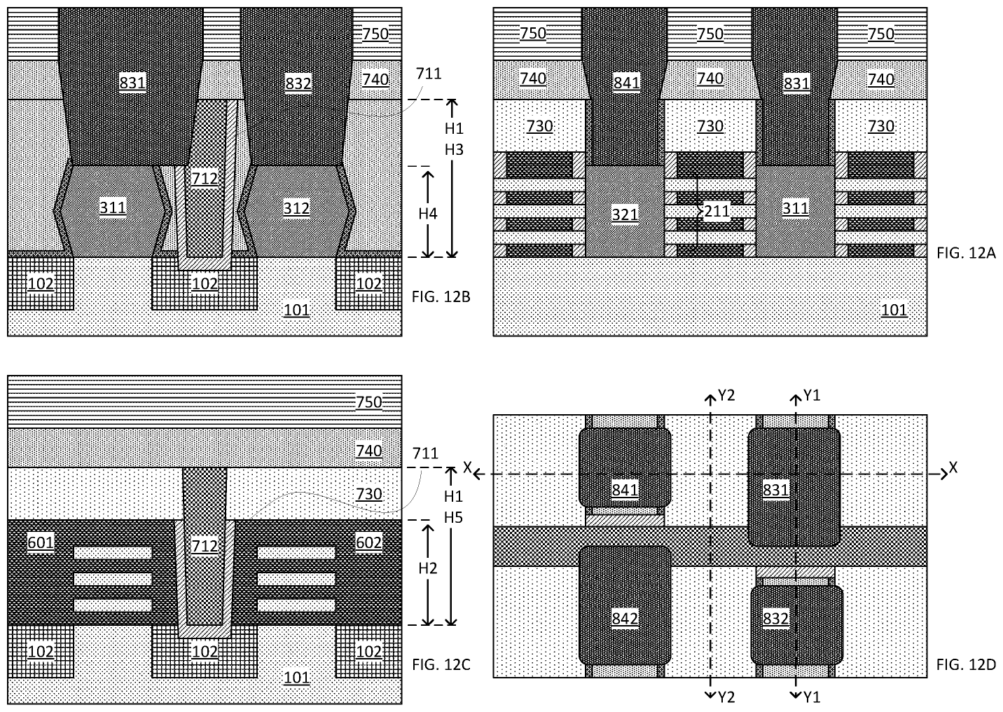

FIGS. 12A, 12B, and 12C are demonstrative illustrations of cross-sectional views, and FIG. 12D is a simplified illustration of top view, of a semiconductor structure in a step of manufacturing thereof according to one embodiment of present invention. More particularly, following the step illustrated in FIGS. 11A-11D, embodiments of present invention provide selectively removing the portion of the protective liner 411 above the source/drain regions of the transistors, and depositing a silicide liner of, for example, titanium (Ti), nickel (Ni), platinum (Pt), and/or nickel-platinum (NiPt); an adhesive metal liner of, for example, titanium-nitride (TiN); and a conductive metal fill of, for example, tungsten (W), cobalt (Co), aluminum (Al), and/or copper (Cu), to be in contact with the source/drain regions of the transistors, thereby forming source/drain contacts. A first source/drain contact 831 may be formed to be in contact with the first source/drain region 311. The first source/drain contact 831 may extend into the gate cut structure 700 to be directly on top of a portion of the dielectric liner 711 and partially on top of the dielectric filler 712. Other source/drain contacts such as source/drain contacts 832, 841, and 842 may be formed in the respective openings 812, 821, and 822.

In one embodiment, as is illustrated in FIG. 12C, the dielectric filler 712 may have a first height H1 and the dielectric liner 711 in the first region 791, between the first and the second gate 601 and 602 of the first and the second transistor 201 and 202, may have a second height H2 and the second height H2 is smaller than the first height H1. In another embodiment, as is illustrated in FIG. 12B, the dielectric liner 711 in the second region 792, between the first and the second source/drain region 311 and 312 of the first and the second transistor 201 and 202, may have a third height H3 that is substantially same as the first height H1 of the dielectric filler 712. In other words, the dielectric liner 711 may be coplanar with the dielectric filler 712. Moreover, the dielectric liner 711 may be coplanar with the dielectric cap 730 as well and the third height H3 may be substantially same as a fifth height H5 of the dielectric cap 730. In the meantime, a portion of the dielectric liner 711, i.e., the portion which is close to the first source/drain region 311 of the first transistor 201, may be recessed thereby having a fourth height H4. The fourth height H4 is smaller than the third height H3. The portion of the dielectric liner 711 having the fourth height H4 is directly below the first source/drain contact 831 of the first transistor 201.

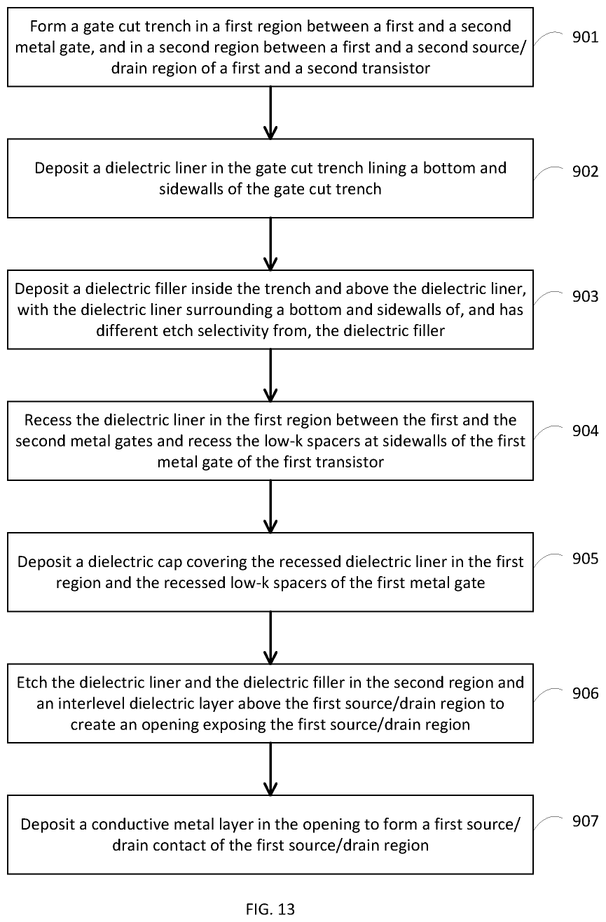

FIG. 13 is a demonstrative illustration of a flow-chart of a method of manufacturing a semiconductor structure according to embodiments of present invention. The method includes (901) forming a gate cut trench in a first region between a first and a second metal gate, and in a second region between a first and a second source/drain region of a first and a second transistor respectively; (902) depositing a dielectric liner in the gate cut trench with the dielectric liner lining a bottom and sidewalls of the trench; (903) depositing a dielectric filler inside the trench and above the dielectric liner with the dielectric liner surrounding a bottom and sidewalls of the dielectric filler, the dielectric liner and the dielectric filler have different etch selectivity; (904) recessing the dielectric liner in the first region between the first and the second metal gate and recessing the low-k spacers at the sidewalls of the first metal gate; (905) depositing a dielectric cap covering the recessed dielectric liner in the first region and the recessed low-k spacers of the first metal gate; (906) etching the dielectric liner and the dielectric filler in the second region between the first and the second source/drain region of the first and the second transistor, and etch an interlevel dielectric layer above the first source/drain region of the first transistor thereby exposing the first source/drain region of the first transistor; and (907) depositing a conductive metal layer in the opening to form a first source/drain contact of the first source/drain region of the first transistor.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions above have been presented for the purposes of illustration of various embodiments of present invention and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a gate cut structure comprising a first region, a second region, a dielectric liner, and a dielectric filler; the first region being between a first and a second gate of a first and a second transistor respectively; the second region being between a first and a second source/drain region of the first and the second transistor respectively; and the dielectric liner surrounding the dielectric filler at a bottom and sidewalls of the dielectric filler in the first and the second region,
wherein the dielectric filler has a first height and the dielectric liner in the first region between the first and the second gate of the first and the second transistor has a second height, and the second height is smaller than the first height.

2. The semiconductor structure of claim 1, wherein the dielectric liner in the second region between the first and the second source/drain region of the first and the second transistor has a third height and a fourth height, wherein the third height of the dielectric liner is substantially same as the first height of the dielectric filler.

3. The semiconductor structure of claim 2, wherein the fourth height is smaller than the third height and a portion of the dielectric liner having the fourth height is directly below a first source/drain contact of the first transistor.

4. The semiconductor structure of claim 3, further comprising a dielectric cap above the first and the second gate of the first and the second transistor, wherein the dielectric cap has a top surface that is co-planar with the dielectric filler and has a fifth height that is substantially same as the first height of the dielectric filler and substantially same as the third height of the dielectric liner.

5. The semiconductor structure of claim 4, wherein the dielectric cap is directly on top of the dielectric liner between the first and the second gate of the first and the second transistor, the dielectric cap has an etch selectivity that is different from an etch selectivity of the dielectric filler and different from an etch selectivity of the dielectric liner.

6. The semiconductor structure of claim 1, wherein the first and the second transistor include low-k spacers at sidewalls of the first and the second gate respectively, and the dielectric liner comprises a low-k dielectric material that is substantially same materially as the low-k spacers.

7. The semiconductor structure of claim 1, wherein the dielectric filler has an etch selectivity that is different from an etch selectivity of the dielectric liner and is substantially same materially as an interlevel dielectric layer on top of the first and the second source/drain region of the first and the second transistor.

8. A method comprising:
forming a gate cut trench in a first region between a first and a second metal gate of a first and a second transistor respectively and in a second region between a first and a second source/drain region of the first and the second transistor respectively;
depositing a dielectric liner in the gate cut trench, the dielectric liner lining sidewalls and a bottom of the gate cut trench;
depositing a dielectric filler inside the gate cut trench above the dielectric liner, the dielectric liner thereby surrounding a bottom and sidewalls of the dielectric filler;
depositing a dielectric cap covering the dielectric liner in the first region;
etching the dielectric liner in the second region to create an opening exposing the first source/drain region of the first transistor; and
depositing a conductive metal layer in the opening to form a first source/drain contact of the first transistor.

9. The method of claim 8, wherein the first and the second transistor have low-k spacers at sidewalls of the first and the second metal gate respectively, and an interlevel dielectric (ILD) layer covering the first and the second source/drain region respectively.

10. The method of claim 9, wherein depositing the dielectric cap comprising:
recessing the dielectric liner in the first region and the low-k spacers at sidewalls of the first metal gate of the first transistor; and
depositing the dielectric cap above the recessed dielectric liner and above the recessed low-k spacers.

11. The method of claim 10, further comprising recessing the first and the second metal gate to expose the dielectric liner in the first region and the low-k spacers at sidewalls of the first metal gate of the first transistor before recessing the dielectric liner and the low-k spacers.

12. The method of claim 11, further comprising planarizing a top surface of the dielectric cap to expose the ILD layer covering the first source/drain region of the first transistor.

13. The method of claim 12, wherein etching the dielectric liner further comprises etching the ILD layer in a selective etching process to create the opening, the opening being self-aligned with the first source/drain region of the first transistor.

14. The method of claim 13, wherein etching the dielectric liner further comprises etching the dielectric filler to form the first source/drain contact of the first transistor, the first source/drain contact of the first transistor being partially on top of the dielectric liner.

15. A semiconductor structure comprising:
a gate cut structure having a first region between a first and a second metal gate of a first and a second transistor respectively and a second region between a first and a second source/drain region of the first and the second transistors respectively; the gate cut structure including a dielectric liner and a dielectric filler, the dielectric liner surrounding the dielectric filler at a bottom and sidewalls thereof,
wherein the dielectric filler has a first height, and the dielectric liner has a second height in the first region and a third and a fourth height in the second region, wherein the second height is smaller than the first height, the third height is substantially same as the first height, and the fourth height is smaller than the third height.

16. The semiconductor structure of claim 15, wherein a portion of the dielectric liner having the fourth height is directly below a first source/drain contact of the first transistor.

17. The semiconductor structure of claim 16, further comprising a dielectric cap above the first and the second metal gate of the first and the second transistor, wherein the dielectric cap is planarized to has a top surface that is co-planar with a top surface of the dielectric filler.

18. The semiconductor structure of claim 17, wherein the dielectric cap is directly on top of the dielectric liner in the first region between the first and the second gate of the first and the second transistor, the dielectric cap comprises a dielectric material that enables a selective etching process relative to the dielectric filler and the dielectric liner.

19. The semiconductor structure of claim 15, wherein the first and the second transistor include low-k spacers at sidewalls of the first and the second metal gate respectively, and the dielectric liner is a low-k dielectric material that is substantially same as the low-k spacers.

20. The semiconductor structure of claim 15, wherein the dielectric filler has an etch selectivity that is different from an etch selectivity of the dielectric liner and is substantially same as an etch selectivity of an interlevel dielectric layer on top of the first and the second source/drain region of the first and the second transistor.
